(19) United States
(12) Patent Application Publication
(10) Pub. No.: US 2003/0107050 A1
(43) Pub. Date: Jun. 12, 2003

(54) High frequency high voltage silicon-on-insulator device with mask variable inversion channel and method for forming the same

(75) Inventors: Theodore J. Letavic, Putnam Valley, NY (US); Mark R. Simpson, White Plains, NY (US); Lucian Remus Albu, New York, NY (US); Satyendranath Mukherjee, Yorktown Heights, NY (US)

Correspondence Address: PHILIPS ELECTRONICS NORTH AMERICAN CORP, 580 WHITE PLAINS RD, TARRYTOWN, NY, 10591, US

(73) Assignee: Koninklijke Philips Electronics N.V.

(21) Appl. No.: 10/015,640

(22) Filed: Dec. 10, 2001

(51) Int. Cl. H01L 29/74

(52) U.S. Cl. 257/148

(57) ABSTRACT

A high frequency high voltage semiconductor device having a shifted doping profile and method for forming the same are provided. Specifically, the present invention provides a semiconductor device (<250V) in which the doping profile is shifted towards the source or body region of the device. The shift in doping profile under the present invention allows both transconductance and capacitance to be optimized so that a SOI device can operate at high frequencies.

### BACKGROUND OF THE INVENTION

1. Field of the Invention

The present invention generally relates to a high frequency high voltage semiconductor (SOI) device. More particularly, the present invention relates to a high frequency semiconductor device having a shifted doping profile, and method for forming the same.

2. Background Art

In electronic display applications, it is desirable to obtain high frequency performance from semiconductor devices. In general, a figure of merit that must be optimized for high frequency performance is transconductance divided by capacitance. Specifically, channel transconductance should be as high as possible and parasitic capacitance should be as low as possible to provide high frequency performance from a silicon-on-insulator (SOI) device.

Heretofore, many have attempted to improve the basic SOI (silicon-on-insulator) structure and performance. U.S. Pat. Nos. 5,969,387 and 6,221,737, both commonly assigned with the present application and herein incorporated by reference, disclose a LDMOS S01 device (and method for forming the same) having a graded top oxide and drift region in an attempt to yield a better tradeoff between breakdown voltage and saturation current. However, the formation of the graded top oxide and drift region of these references relies upon a two-dimensional oxidation process, which fails to provide a way to increase transconductance while decreasing capacitance.

U.S. Pat. Nos. 5,246,870 and 5,300,448, both commonly assigned with the present application and herein incorporated by reference, attempt to improve breakdown voltage by providing a linear doping profile in the drift region of a semiconductor device. Specifically, these SOI devices are provided with various features, such as a thinned silicon portion and a linear lateral doping intensity profile, in an attempt to provide increased breakdown voltage. However, to maintain high breakdown voltage, the total amount of conduction charge near the source side of the drift region must be kept very small. This often leads to bottlenecking for current flow, and preventing optimum reduction in conduction losses. In addition neither reference provides a way to optimize both transconductance and capacitance.

U.S. Pat. No. 6,232,636, commonly assigned with the present application and herein incorporated by reference, discusses methods for forming a lateral charge profile in a semiconductor device. In particular, this reference teaches a lateral charge profile having multiple slopes. However, the reference fails to provide a way to increase transconductance while decreasing capacitance.

In addition, each of the above-incorporated references discusses devices that have been optimized for performance around 650V. Since display applications generally have voltages in the range of <250V, the device designs of these references lack optimal area efficiency.

In view of the foregoing, there exists a need for a semiconductor device capable of operating at high frequencies. In addition, a need exists for a high frequency semiconductor device in which both transconductance and capacitance are optimized. A further need exists for a high frequency semiconductor device to be area efficient. Another need exists for a high frequency semiconductor device that has a shifted doping profile.

### SUMMARY OF THE INVENTION

In general, the present invention provides a high frequency semiconductor device having a shifted doping profile, and method for forming the same. Specifically, under the present invention a doping profile of drift region is shifted towards a source or body region of the device so that an origin of the doping profile is within the body region. The shift in the doping profile reduces the channel length, which increases the transconductance as well as the maximum current of the device. The increase in maximum current allows the device size to be reduced, which reduces the capacitance of the device. The shift in doping profile is accomplished by shifting the mask, through which the doping ions are implanted, towards the body region. This technique results in a process in which lateral diffused MOS devices can be fabricated with varying inversion channel lengths without a change in process flow of process modules. This technique also allows for multiple devices within the same process to have different transconductance and/or current (performance) characteristics without increasing cost.

According to a first aspect of the present invention, a high frequency semiconductor device having a shifted doping profile is provided. The device comprises: (1) a buried oxide layer formed over a semiconductor substrate; and (2) a silicon layer formed over the buried oxide layer, wherein an origin of a doping profile of the silicon layer is within a body region of the device.

According to a second aspect of the present invention, a high frequency semiconductor device having a shifted doping profile is provided. The device comprises: (1) a buried oxide layer formed over a semiconductor substrate; (2) a silicon layer formed over the buried oxide layer, wherein the silicon layer comprises a source region, a body region, a drift region, and a drain region; and (3) a top oxide layer formed over the silicon layer, wherein a doping profile of the silicon layer has an origin within the body region, approximately 2 to 4 μm from an edge of the top oxide layer.

According to a third aspect of the present invention, a method for forming a high frequency semiconductor device having a shifted doping profile is provided. The method comprises: (1) forming a buried oxide layer over a semiconductor substrate; (2) forming a silicon layer over the buried oxide layer; (3) forming a doping profile in the silicon layer having an origin within a body region of the device; and (4) forming a top oxide layer over the silicon layer.

Therefore, the present invention provides a high voltage semiconductor device having a shifted doping profile and method for forming the same.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts semiconductor device, in accordance with the present invention.

FIG. 2 depicts a partial view of the semiconductor device of FIG. 1 as doping ions are implanted.

FIG. 3 depicts a view of doping mask position for the device of FIG. 1 as compared to a doping mask position for a related art device.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

In general, the present invention allows a silicon-on-insulator (SOI) device (<250V) to operate at high frequencies by increasing the doping in the silicon layer of the device and reducing the channel length. The increase in doping results from a shift of the doping profile towards a source or a body region of the device. Specifically, under the present invention the doping profile is shifted so that an origin of the doping profile is within the body region. The shift in the doping profile increases doping along the silicon layer and reduces the channel length, which increases both the transconductance and the maximum current of the device. The increase in maximum current allows the device size to be reduced by the size of the increase in maximum current, which likewise reduces the capacitance of the device by the same value. The shift in doping profile is accomplished by shifting the photoresist mask, through which the doping ions are implanted, towards the body region. The resulting doping profile will be shifted in the same direction and by the same distance as the photoresist mask.

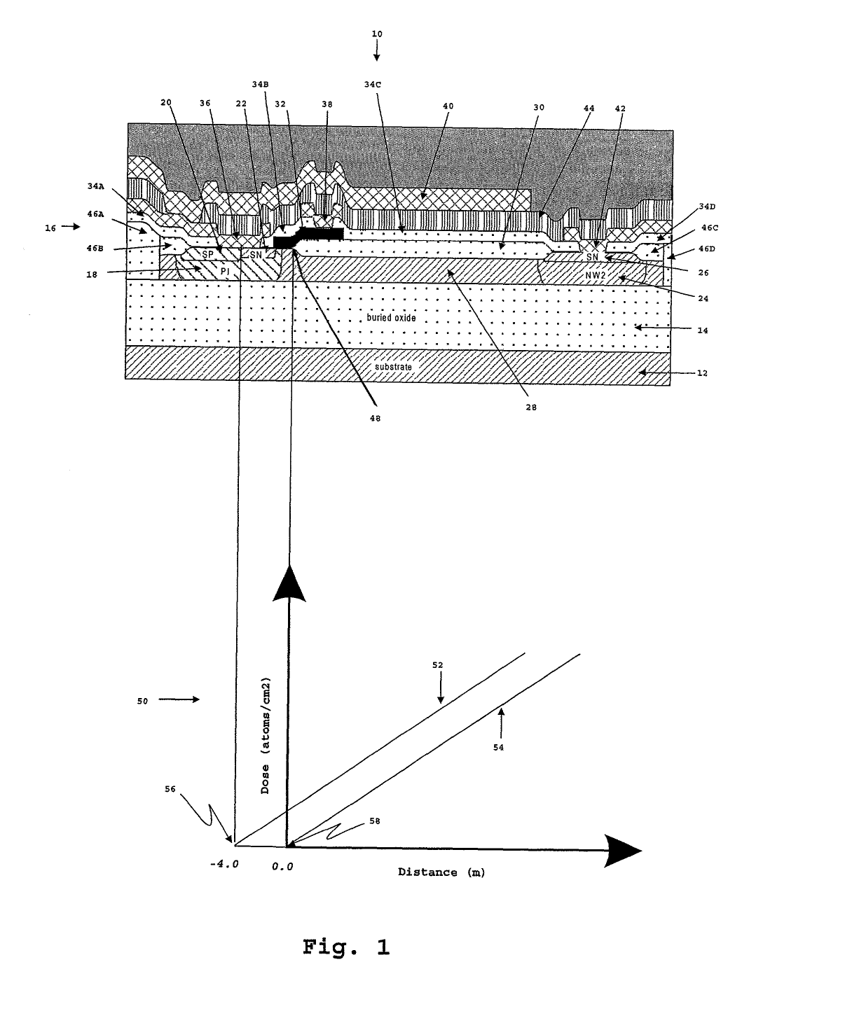

Referring now to FIG. 1, a semiconductor device 10 according to the present invention is shown. As depicted, buried oxide layer 14 is deposited over semiconductor substrate 12. Silicon layer 16 is formed over buried oxide layer 14 and generally includes P-type body or channel region 18, P+ source region 20, N+ source region 22, N+ drain region 26, N-Well region 24, and drift region 28.

Under the present invention, silicon layer 16 is provided with a doping profile that is shifted towards body region 18. Specifically, graph 50 depicts doping profiles 52 and 54 of implantation (atoms/cm²) versus distance (μm). Distance refers to the lateral distance along silicon layer 16 from a starting point (e.g., edge 48 of top oxide layer 30) towards N+ drain region 26. Doping profile 52 is the shifted profile according to the present invention, while doping profile 54 pertains to related art devices. As can be seen, doping profile 54 for related art devices has an origin 58 that is approximately aligned with edge 48 of top oxide layer 30. Thus at edge 48, silicon layer 16 has a distance and an implantation dose of approximately zero (for profile 54). Under the present invention, the doping profile 52 is shifted so that origin 56 is within body region 16 (as shown). By shifting doping profile 52 in this manner, a higher implantation dose occurs throughout silicon layer 16 (as shown by comparing doping profile 52 to doping profile 54). In one embodiment of the present invention, the doping profile is shifted towards body region 18 (e.g., offset from edge 48) by approximately 4.0 μm for charge gradings on the order of 2-3 e¹⁵ cm²/μm. For example, FIG. 1 shows that origin 56 is approximately 4.0 μm from edge 48 and origin 58. In another embodiment, the doping profile is shifted anywhere in the range of approximately 2.0-4.0 μm. It should be understood that although a linear doping profile is depicted in FIG. 1, the present invention could be applied to non-linear and/or non-uniform doping profiles.

By shifting doping profile 52 so that origin 56 is within body region 18, the channel doping of device 10 is modulated (i.e., the channel length of device 10 is reduced). Specifically, because the channel length of device 10 is defined as when the P-type dopant (of body region 18) equals the N-type dopant (of drift region 28), the shift of the N-type doping profile towards body region 18 reduces the channel length and increases the transconductance of device 10 (e.g., by increasing the doping in the area to where the doping profile is shifted). As will be described in further detail below, the shift in doping profile and variance in channel length is achieved by shifting the mask through which doping ions are implanted.

In one example, a 160V device was constructed with a 4 μm shift (towards the body region) in the doping profile. The device yielded an increase of approximately 15% in transconductance and an increase of approximately 4550% in maximum current. Moreover, since the size of device could be reduced by the size of the gain in maximum current (e.g., 45-50%), the overall capacitance of device 10 was also reduced by approximately 45-50%. This optimization of transconductance and capacitance allowed the 160V device to operate at approximately 7 GHz. Accordingly, shifting doping profile 52 towards body region 18 in the manner described herein allowed a SOI device to achieve high frequency operation.

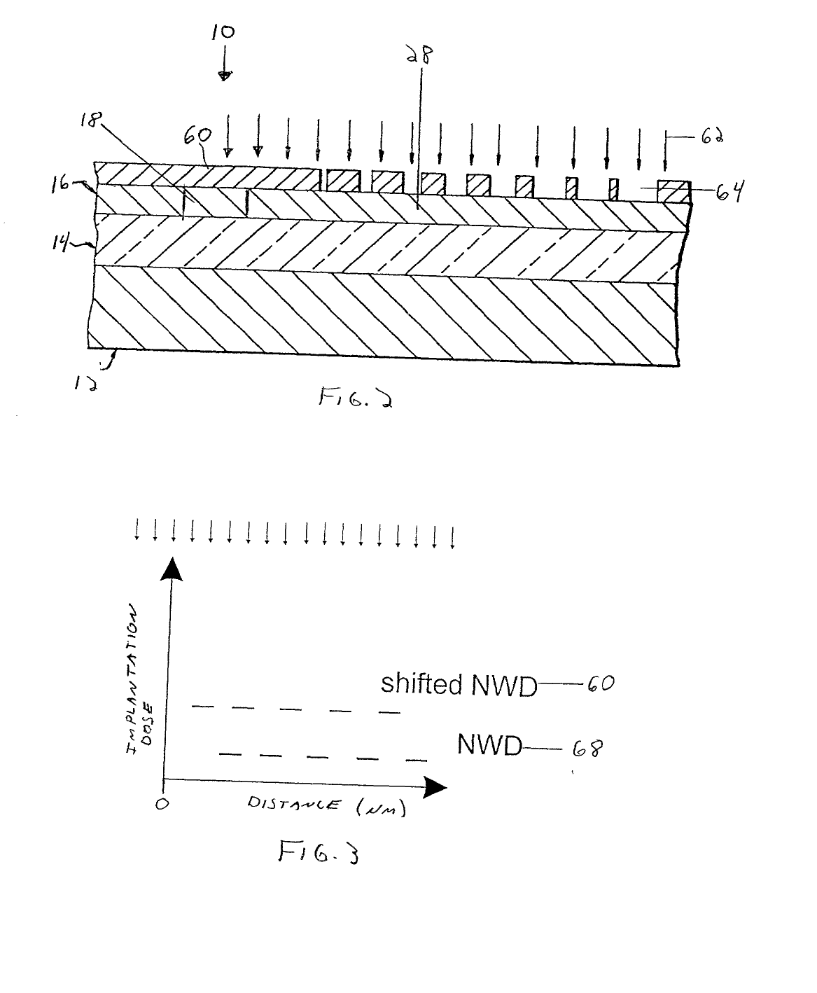

To achieve the shift in doping profile 52, the mask through which the doping ions are implanted must be shifted in the same direction and distance as desired for doping profile 52. Specifically, as shown in FIG. 2, a mask such as photoresist mask 60 is formed over silicon layer 16. Mask includes openings 64 through which ions 62 are implanted. The openings 64 may be made of varying width and/or spacing so as to provide the desired doping profile. In general, phosphorus ions are implanted at an energy level of approximately 100 KeV and at an ion dose of approximately 2×10¹³/cm². (It should be understood that the dose and energy specified depend upon mask openings 64, the thickness of silicon layer 28, the thickness of oxide layers 14, 30, 34, the thickness of nitride layer 44, and the desired doping profile 52.) As shown in FIG. 3, mask 60 (N Well Drift) is positioned closer to edge 48 (e.g., where distance is zero) than mask 68 used to implant ions in related devices. This shifting allows origin 56 of doping profile 52 to be within body region 18, and results in a high frequency high voltage SOI device having a mask-variable inversion channel (as explained above). Specifically, as shown in FIG. 2, the shifted mask position allows ions 62 to be implanted in both body region 18 and drift region 28. In general, origin 56 of doping profile 52 will be shifted or offset by the same distance and in the same direction that mask 60 is shifted. Thus, a 4 μm shift of mask towards body region 18 will result in a comparable 4 μm shift of origin 52 towards body region 18. This provides a fabricator with optimal flexibility in optimizing transconductance and capacitance.

Once the doping ions have been implanted, mask 60 is removed and device 10 is capped with a silicon nitride layer and then annealed. The combination of masking, implanting, and annealing provides the approximate linear variation of doping over the lateral distance of silicon layer 16. Once annealing is complete, another photoresist mask could then be formed over the doped regions, and any silicon nitride remaining from the annealing process could be removed via reactive ion etching. The additional photoresist mask is then removed and device 10 could be thermally oxidized in steam.

Top oxide layer 30 (FIG. 1) is then grown using a Local Oxidation of Silicon (LOCOS) process. This involves growing a pad oxide layer on silicon layer 16 and then depositing a silicon nitride layer on the pad oxide layer. Top oxide layer 30 is then grown to appear as shown. The resulting silicon layer 16 has a thinned lightly doped drain or drift region 28 below top oxide layer 30. Once top oxide layer 30 is formed, a gate oxide is grown and polysilicon gate 32 is-deposited. Once polysilicon gate 32 has been deposited, N+ source region 22, N+ drain region 26, N-Well region 24, P+ source region 20, and channel or body region 18 are defined. As further shown, plate oxide layer 34A-D, source metal 36, gate metal 38, and drain metal 42 could then be formed followed by nitride layer 44 and field plate 40. In addition, device 10 could be provided with additional oxide layers 46A-D to provide isolation between various regions/layers. It should be understood that the steps described for forming device 10 are for illustrative purposes only. For example, the order in which the layers and/or regions are formed could be varied in any means as known in the art.

Among other things, the present invention allows for multiple devices within the same process to have different transconductance and/or current (performance) characteristics without increasing cost. The foregoing description of the preferred embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims. Accordingly, it should be understood that the precise structure of device 10, other than having a shifted doping profile, is not intended to be a limiting feature of the present invention. For example, device 10 could have multiple different oxide and SOI layer thicknesses. Moreover, top oxide layer 30 could be shaped as shown in U.S. Pat. No. 5,246,870. Also, field plate 40 need not be structurally as shown. Rather, field plate 40 could be any known structure. In addition, as indicated above, the precise doping profile is not intended to be limiting. Rather, the doping profile could be linear or non-linear as long as it is shifted as described herein.

1. A high frequency semiconductor device having a shifted doping profile, comprising:
a buried oxide layer formed over a semiconductor substrate; and
a silicon layer formed over the buried oxide layer, wherein an origin of a doping profile of the silicon layer is within a body region of the device.

2. The device of claim 1, wherein the silicon layer comprises a source region, a body region, a drain region, and a drift region,

3. The device of claim 1, further comprising a top oxide layer, wherein the origin of the doping profile is offset approximately 2 to 4 μm from an edge of the top oxide layer.

4. The device of claim 1, further comprising a field plate formed over the top oxide layer and a plate oxide layer formed over the field plate.

5. The device of claim 4, further comprising a source metal, a gate metal, and a drain metal formed over the silicon layer.

6. The device of claim 1, wherein the doping profile is linear.

7. The device of claim 1, wherein the doping profile is non-linear.

8. A high frequency semiconductor device having a shifted doping profile, comprising:
a buried oxide layer formed over a semiconductor substrate;
a silicon layer formed over the buried oxide layer, wherein the silicon layer comprises a source region, a body region, a drift region, and a drain region; and
a top oxide layer formed over the silicon layer, wherein a doping profile of the silicon layer has an origin within the body region, approximately 2 to 4 μm from an edge of the top oxide layer.

9. The device of claim 8, wherein the doping profile is linear.

10. The device of claim 8, wherein the doping profile is non-linear.

11. The device of claim 8, further comprising a field plate formed over the top oxide layer and a plate oxide layer formed over the field plate.

12. The device of claim 11, further comprising a source metal, a gate metal, a drain metal formed over the silicon layer.

13. The device of claim 8, wherein the device has a transconductance approximately 15% higher and a maximum current approximately 45% higher than a device having a doping profile origin approximately aligned with the edge of the top oxide layer.

14. A method for forming a high frequency semiconductor device having a shifted doping profile, comprising:
forming a buried oxide layer over a semiconductor substrate;
forming a silicon layer over the buried oxide layer;
forming a doping profile in the silicon layer having an origin within a body region of the device; and
forming a top oxide layer over the silicon layer.

15. The method of claim 14, wherein forming a doping profile in the silicon layer having an origin within a source region of the device comprises:
positioning a mask over the silicon layer; and
implanting ions through openings in the mask so that the origin of the doping profile is offset from an edge of the top oxide layer by a predetermined distance.

16. The method of claim 15, wherein the predetermined distance is approximately 2 to 4 μm.

17. The method of claim 14, wherein forming a silicon layer over the buried oxide layer comprises forming a silicon layer having a source region, a body region, a drift region, and a drain region over the buried oxide layer.

18. The method of claim 14, wherein the doping profile is linear.

19. The method of claim 14, wherein the doping profile is non-linear.

20. The method of claim 14, further comprising:
forming a field plate over the top oxide layer;
forming a plate oxide over the field plate; and
forming a source metal, a gate metal, and a drain metal over the silicon layer.
